(19) United States
(12) Patent Application Publication
(10) Pub. No.: US 2012/0132985 A1
(43) Pub. Date: May 31, 2012

(54) NON-VOLATILE SEMICONDUCTOR MEMORY DEVICE AND METHOD OF MANUFACTURING NON-VOLATILE SEMICONDUCTOR MEMORY DEVICE

(75) Inventors: Naoki KAI, Mie (JP); Satoshi Nagashima, Mie (JP)

(73) Assignee: KABUSHIKI KAISHA TOSHIBA, Minato-ku (JP)

(21) Appl. No.: 13/237,363

(22) Filed: Sep. 20, 2011

(30) Foreign Application Priority Data
Nov. 30, 2010 (JP) 2010-266982

(51) Int. Cl. H01L 29/792; H01L 21/336

(52) U.S. Cl. 257/326; 257/324; 438/261; 257/E29.309; 257/E21.422

(57) ABSTRACT

According to one embodiment, a plurality of memory cells are provided on a semiconductor substrate. In each memory cell, a control gate electrode is provided on a charge accumulation layer with an inter-electrode insulation film interposed between the control gate electrode and the charge accumulation layer, an air gap is provided between the charge accumulation layers adjacent to each other in a word line direction, and an insulation film disposed below the inter-electrode insulation film is divided into an upper part and a lower part by the air gap.

### CROSS-REFERENCE TO RELATED APPLICATIONS

This application is based upon and claims the benefit of priority from Japanese Patent Application No. 2010-266982, filed on Nov. 30, 2010; the entire contents of which are incorporated herein by reference.

### FIELD

Embodiments described herein relate generally to a non-volatile semiconductor memory device and a method of manufacturing a non-volatile semiconductor memory device.

### BACKGROUND

In a non-volatile semiconductor memory device such as a NAND-type flash memory, if a memory cell is miniaturized to achieve high integration, the distance between adjacent word lines and the distance between adjacent bit lines are reduced. Therefore, the parasitic capacitance between floating gate electrodes adjacent in the word line direction or the bit line direction. This may result in a significant reduction on a write speed of storage devices of a generation in which a memory cell transistor has a gate length of 1X nm or less.

### BRIEF DESCRIPTION OF THE DRAWINGS

FIG. 1 is a perspective view illustrating a schematic configuration of a memory cell of a non-volatile semiconductor memory device according to a first embodiment;

FIG. 2 is a plan view illustrating a schematic configuration of a memory cell array of a non-volatile semiconductor memory device according to a second embodiment;

FIGS. 3A to 13A, FIGS. 3B to 13B, FIGS. 11C to 13C and

FIGS. 11D to 13D are sectional views illustrating a method of manufacturing a non-volatile semiconductor memory device according to a third embodiment;

FIGS. 14A to 18A and FIGS. 14B to 18B are sectional views illustrating a method of manufacturing a non-volatile semiconductor memory device according to forth embodiment.

### DETAILED DESCRIPTION

In a non-volatile semiconductor memory device of an embodiment, a plurality of memory cells, an air gap, and an insulation film are provided. In the plurality of memory cells, control gate electrodes are provided on corresponding charge accumulation layers through an inter-electrode insulation film. The air gap is provided between the charge accumulation layers adjacent in a word line direction. The insulation film is disposed below the inter-electrode insulation film and divided into an upper layer and a lower layer by the air gap.

Hereinafter, non-volatile semiconductor memory devices of embodiments will be described with reference to the accompanying drawings. In addition, the invention is not limited to the embodiments.

### First Embodiment

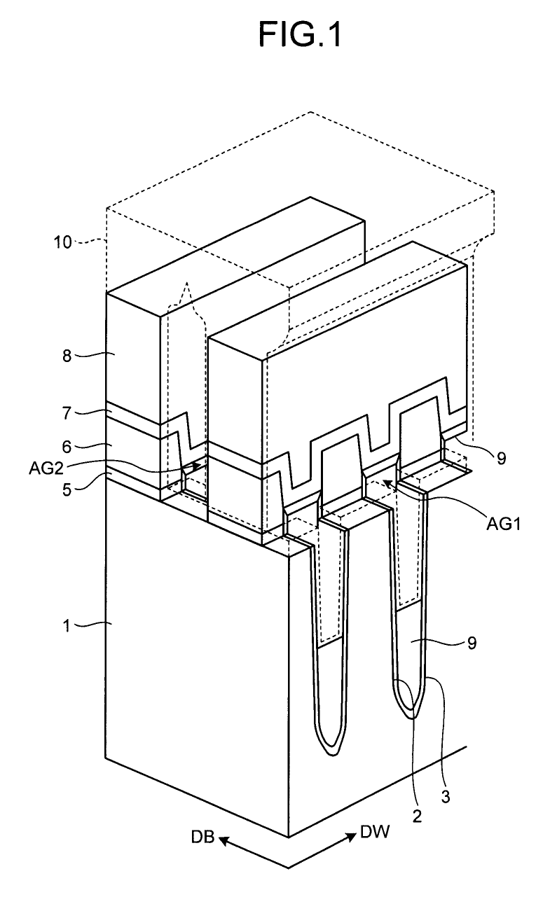

FIG. 1 is a perspective view illustrating a schematic configuration of a memory cell of a non-volatile semiconductor memory device according to a first embodiment.

In FIG. 1, trenches 2 are formed along the bit line direction DB in a semiconductor substrate 1, and an active area of a memory cell formed on the semiconductor substrate 1 is divided by the trench 2. In addition, the active area of the memory cell refers to a channel region and source/drain regions of a memory transistor provided in the memory cell. Furthermore, a material of the semiconductor substrate 1, for example, may be selected from the group consisting of Si, Ge, SiGe, SiC, SiSn, PbS, GaAs, InP, GaP, GaN, GaInAsP, ZnSe and the like.

Furthermore, a sidewall dielectric film 3 is formed on the sidewall of each trench 2. An element isolation insulation film 9 is buried in each trench 2, with the sidewall dielectric film 3 being disposed between the trench 2 and the element isolation insulation film 9, up to a midway point of the trench 2 from the bottom. In addition, as the sidewall dielectric film 3 and the element isolation insulation film 9, for example, a silicon oxide film may be used. In detail, as the sidewall dielectric film 3, for example, a chemical vapor deposition (CVD) oxide film, an atomic layer deposition (ALD) oxide film and the like may be used. Furthermore, as the element isolation insulation film 9, for example, a high density plasma (HDP) oxide film and the like may be used.

Furthermore, in the active area on the semiconductor substrate 1, a floating gate electrode 6 is formed for each memory cell with a tunnel insulation film 5 formed therebetween. The floating gate electrode 6 can be used as a charge storage layer. In addition, as the tunnel insulation film 5, for example, a thermal oxide film or a thermal oxynitride film may be used. Alternatively, a CVD oxide film or a CVD oxynitride film may be used. Further alternatively, an insulation film containing Si therein or an insulation film having Si embedded like a dot may be used. As the floating gate electrode 6, polysilicon doped with N-type impurities or P-type impurities, a metal film using Mo, Ti, W, Al, Ta or the like, a poly metal film, or a nitride film may be used.

Control gate electrodes 8 are formed on the floating gate electrodes 6 with an inter-electrode insulation film 7 being interposed therebetween to extend in the word line direction DW. In addition, the control gate electrode 8 may constitute a word line. In order to improve a coupling ratio between the floating gate electrode 6 and the control gate electrode 8, the control gate electrode 8 may be formed to wrap around the sidewalls of the floating gate electrode 6.

A cover insulation film 10 is formed on the control gate electrodes 8. In addition, as the inter-electrode insulation film 7, for example, a silicon oxide film or a silicon nitride film may be used. Also, a stack structure (for example, an oxide-nitride-oxide (ONO) film) of a silicon oxide film and a silicon nitride film may be used. Also, a high dielectric constant film such as an aluminum oxide film or a hafnium oxide film may be used. Also, a stack structure of a low dielectric constant film such as a silicon oxide film or a silicon nitride film and a high dielectric constant film may be used. As the control gate electrode 8, polysilicon doped with N type impurities or P type impurities may be used. Also, as the control gate electrode 8, a metal film using Mo, Ti, W, Al, Ta or the like, or a poly metal film may be used. Furthermore, as the cover insulation film 10, for example, a silicon oxide film may be used.

Below the inter-electrode insulation film 7, the element isolation insulation film 9 is separated into an upper film and a lower film so that an air gap AG1 can be formed between the floating gate electrodes 6 adjacent in the word line direction DW. The air gap AG1 is filled with gas. For this instance, the element isolation insulation film 9 of an upper side divided by the air gap AG1 may be stacked under the inter-electrode insulation film 7, and the element isolation insulation film 9 of a lower side may be disposed in the trench 2. Furthermore, the element isolation insulation film 9, which is divided by the air gap AG1 into the upper side and the lower side, may be made of the same material so that the upper side and the lower side have the same film quality. The air gap AG1 is formed to fill the rest of the trench 2, so that the air gap AG1 may reach a deeper position in the trench 2 than the lower surface of the floating gate electrode 6. Furthermore, the air gap AG1 may be disposed to run under the control gate electrode 8 so as to be continuously formed in the trench 2 over adjacent memory cells.

Furthermore, the sidewall dielectric film 3 may have an inclined upper end surface that reflects a raw material gas of the element isolation insulation film 9 when the element isolation insulation film 9 is buried in the trench 2. Then, the raw material gas of the element isolation insulation film 9 is reflected by the inclined surface of the sidewall dielectric film 3 when the element isolation insulation film 9 is formed by HDP-CVD, so that the element isolation insulation film 9 is not formed in the vicinity of the upper end of the sidewall dielectric film 3, so that the air gap AG1 can be formed between parts of the element isolation insulation film 9.

Furthermore, the cover insulation film 10 extends between the control gate electrodes 8 such that a space between the floating gate electrodes 6 is not completely buried, so that an air gap AG2 is formed between the floating gate electrodes 6 adjacent in the bit line direction DB. The air gap AG2 is filled with gas. In addition, an upper part and a lower part of the air gap AG2 may be asymmetrical and the upper end of the air gap AG2 may have a steeple shape. Furthermore, the air gap AG2 may be continuously formed to extend over the memory cells adjacent in the word line direction DW, and the air gaps AG1 and AG2 may be connected to each other at an intersection thereof.

The air gaps AG1 and AG2 (for example, relative permittivity of air is 1) are provided between the floating gate electrodes 6, so that the parasitic capacitance between the floating gate electrodes can be reduced as compared with the case in which an insulation material (for example, relative permittivity of a silicon oxide film is 3.9) is buried between the floating gate electrodes 6. Consequently, it is possible to reduce the interference of an electric field between adjacent cells due to the parasitic capacitance between the floating gate electrodes, thereby narrowing the distribution width of a threshold voltage of a cell transistor.

Furthermore, the air gap AG1 reaches the deeper position than the lower surface of the floating gate electrode 6, that is, the air gap AG1 is disposed at a position lower than the lower surface of the floating gate electrode 6, the fringe capacitance between the control gate electrode 8 and the semiconductor substrate 1 can be reduced. Consequently, it is possible to improve the coupling ratio between the floating gate electrode 6 and the control gate electrode 8, which lowers a write voltage.

Furthermore, the air gap AG1 is formed at the time when the film forming for the element isolation insulation film 9 is performed, so that it is not necessary to perform wet etching of the element isolation insulation film 9 at the time of forming the air gap AG1, and even a case in which the tunnel insulation film 5 and the inter-electrode insulation film 7 are made of the same material as the element isolation insulation film 9, it is possible to prevent damage to the tunnel insulation film 5 and the inter-electrode insulation film 7.

### Second Embodiment

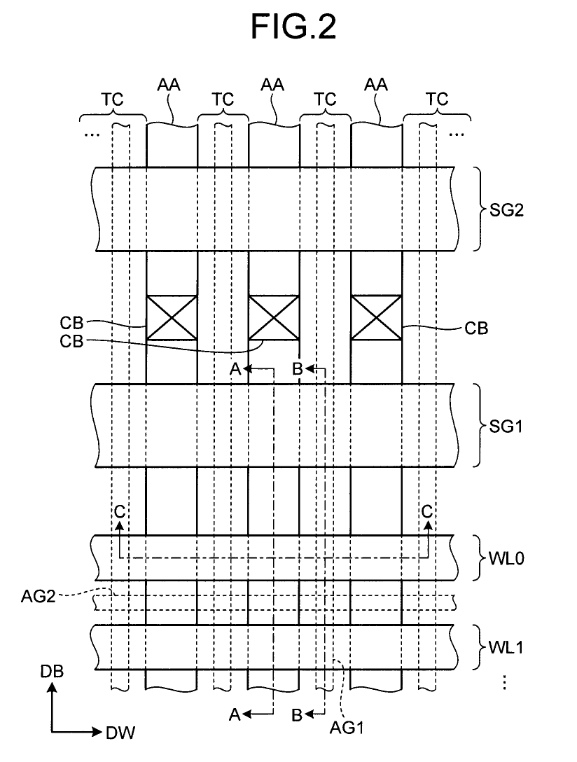

FIG. 2 is a plan view illustrating a schematic configuration of a memory cell array of a non-volatile semiconductor memory device according to a second embodiment.

In FIG. 2, trenches TC are formed along the bit line direction DB and active areas AA are separated from one another by the trenches TC. Furthermore, word lines WL0, WL1, . . . and each of select gate electrodes SG1 and SG2 are formed to extend in the word line direction DW. Bit line contacts CBs are formed on the active areas AA between the select gate electrodes SG1 and SG2, respectively.

Then, air gaps AG1 are formed along the trenches TC formed to extend in the bit line direction DB, respectively. Furthermore, air gaps AG2 are formed every between the word lines WL0, WL1, . . . in the word line direction DW.

The air gaps AG1 may extend under the word lines WL0, WL1, . . . to be continuously formed in the trenches TC over adjacent memory cells. Furthermore, the air gaps AG1 may be formed to exist below the select gate electrodes SG1 and SG2 along the trenches TC, or may be formed to penetrate through the structure disposed below the select gate electrodes SG1 and SG2, along the trenches TC.

The air gaps AG1 are also provided below the select gate electrodes SG1 and SG2, so that it is possible to reduce the fringe capacitance generated in an area from the select gate electrodes SG1 and SG2 and to around a channel region. Consequently, it is possible to improve controllability and drivability of a channel based on a gate electric field, resulting in an improvement in an S factor of a select transistor.

### Third Embodiment

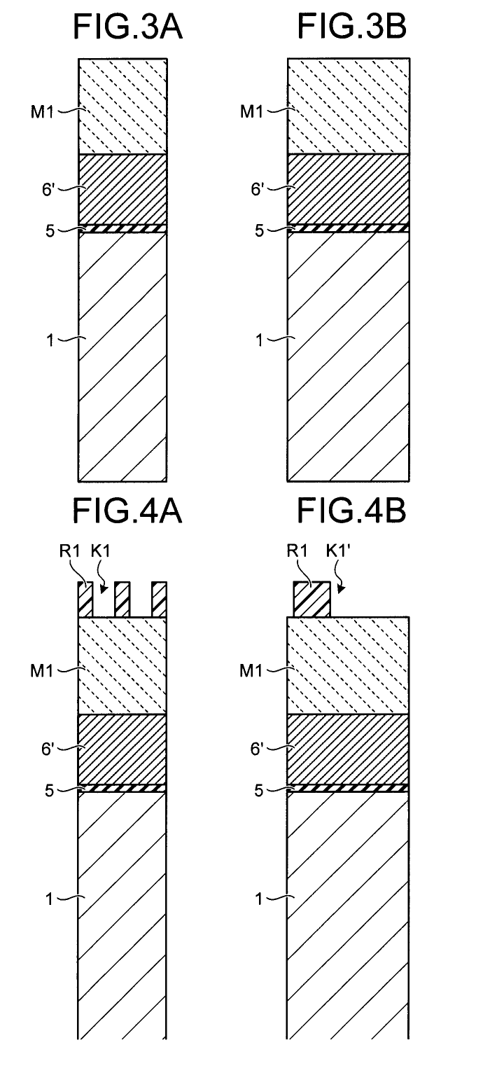

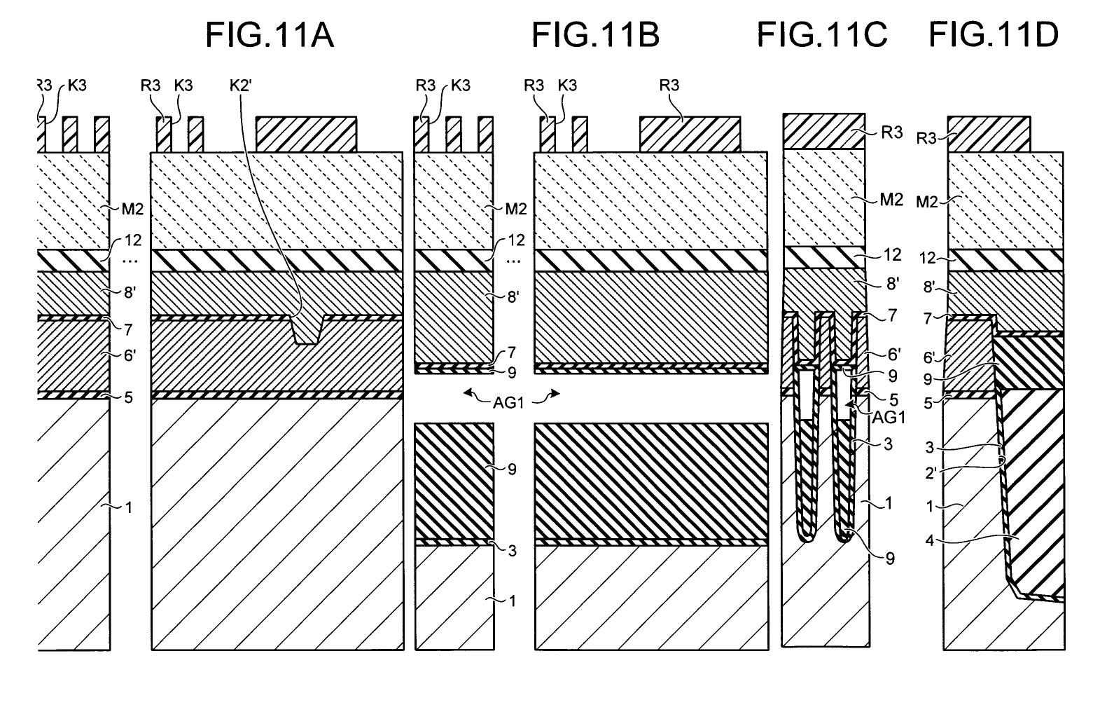

FIGS. 3A to 13A, FIGS. 3B to 13B, FIGS. 11C to 13C and FIGS. 11D to 13D are sectional views illustrating a method of manufacturing a non-volatile semiconductor memory device according to a third embodiment. In detail, FIGS. 11A, 12A and 13A are sectional views taken along line A-A of FIG. 2, FIGS. 11B, 12B and 13B are sectional views taken along line B-B of FIG. 2, FIGS. 3A, 4A, 5A, 6A, 7A, 8A, 9A and 10A and FIGS. 11C, 12C and 13C are sectional views taken along line C-C of FIG. 2, and FIGS. 3B, 4B, 5B, 6B, 7B, 8B, 9B and 10B and FIGS. 11D, 12D and 13D are sectional views taken along a peripheral circuit unit.

In FIGS. 3A and 3B, a tunnel insulation film 5 is formed on a semiconductor substrate 1 using a method such as thermal oxidation. Then, a floating gate electrode material 6′ is formed on the tunnel insulation film 5 using a method such as CVD, and a hard mask M1 is formed on the floating gate electrode material 6′. As the hard mask M1, for example, a silicon oxide film, an amorphous silicon film, a silicon nitride film, a carbon-containing organic film and the like may be used.

Next, as illustrated in FIGS. 4A and 4B, resist patterns R1 with openings K1 and K1′ are formed on the hard mask M1 using a photolithography technique.

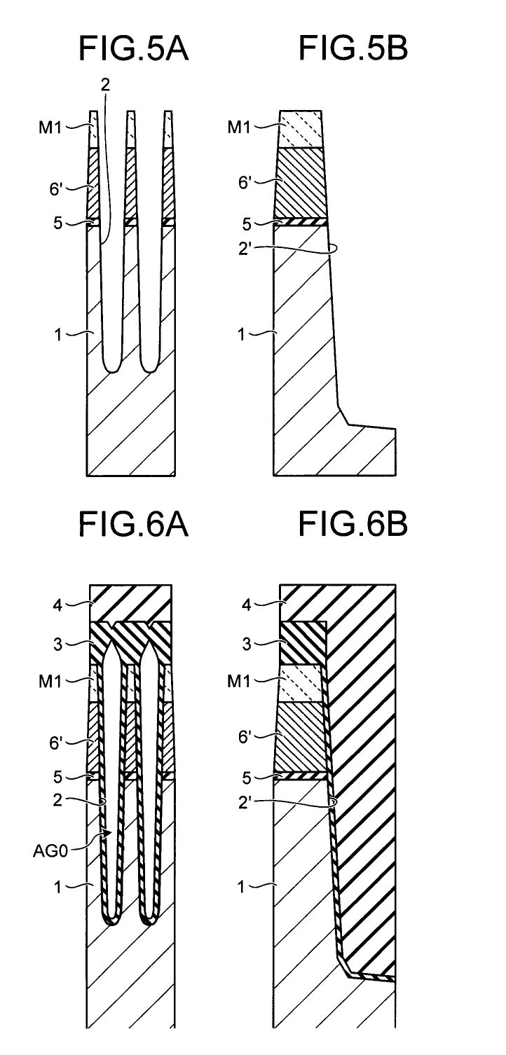

Next, as illustrated in FIGS. 5A and 5B, the hard mask M1 is patterned using the resist pattern R1 as a mask, and then the floating gate electrode material 6′, the tunnel insulation film 5, and the semiconductor substrate 1 are etched using the hard mask M1 as a mask, thereby forming trenches 2 and 2′ in the semiconductor substrate 1. In addition, the trenches 2′ may be used to isolate elements of a peripheral circuit from each other.

Next, as illustrated in FIGS. 6A and 6B, a sidewall dielectric film 3 is deposited on the hard mask M1 using a method such as plasma CVD such that an air gap AG0 may be formed in the trench 2, thereby forming the sidewall dielectric film 3 on the sidewalls of the trenches 2 and 2′. At this time, to form the air gap AG0 in the trench 2, film formation conditions having a poor embedding property may be set. Then, a buried insulation film 4 is formed on the sidewall dielectric film 3 using a method such as coating or CVD such that the entire trench 2′ is buried. At this time, to allow the entire trench 2′ to be buried, film formation conditions a having good embedding property may be set. In addition, as the buried insulation film 4, for example, a chemical vapor deposition (CVD) oxide film, an atomic layer deposition (ALD) oxide film, a spin on glass (SOG) oxide film, or a condensed CVD oxide film and the like may be used.

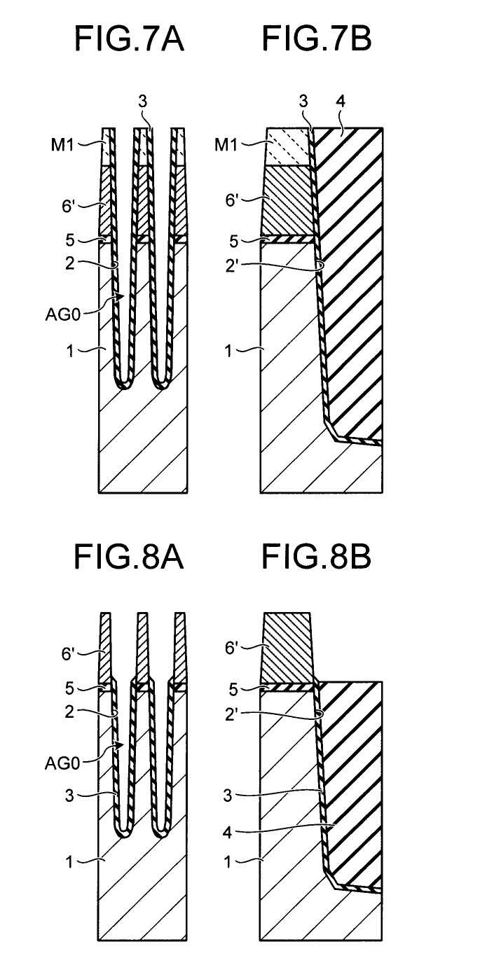

Next, as illustrated in FIGS. 7A and 7B, the buried insulation film 4 and the sidewall dielectric film 3 are planarized using a method such as CMP, thereby exposing the surface of the hard mask M1 and opening the air gap AG0.

Next, as illustrated in FIGS. 8A and 8B, the sidewall dielectric film 3 is etched using anisotropic etching such as RIE, and a part of the sidewall of the floating gate electrode material 6′ is exposed such that the upper end of the sidewall dielectric film 3 reaches the sidewall of the floating gate electrode material 6′. Here, the sidewall dielectric film 3 may be provided at the upper end thereof with an inclined surface that reflects a raw material gas of a buried insulation film 9 when the buried insulation film 9 is buried in the trench 2′ by HDP-CVD.

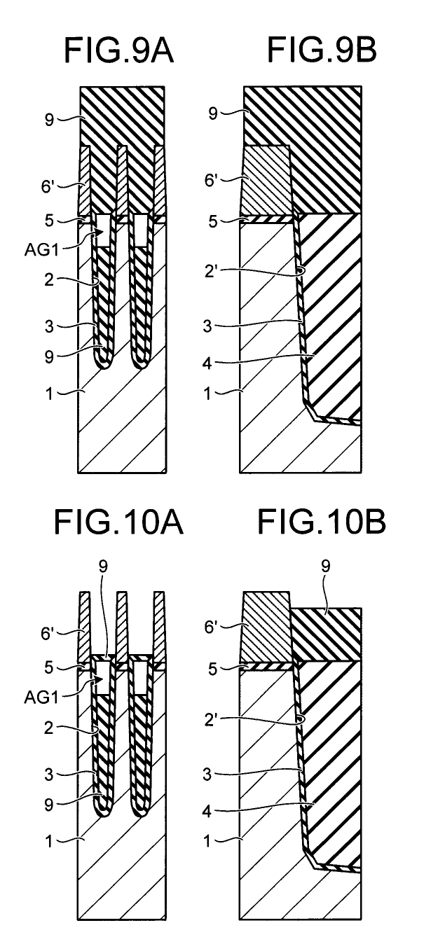

Next, as illustrated in FIGS. 9A and 9B, the buried insulation film 9 is formed on the floating gate electrode material 6′ using a method such as HDP-CVD such that the trenches 2 and 2′ are buried. According to the HDP-CVD, the raw material gas of the buried insulation film 9 is reflected from the inclined surface of the sidewall dielectric film 3, and is reabsorbed onto the floating gate electrode material 6′ on the sidewall dielectric film 3 without being reabsorbed in the trench 2 with a narrow width. Therefore, an air gap AG1 is formed in the buried insulation film 9 in the vicinity of the upper end of the sidewall dielectric film 3, and the buried insulation film 9 is divided into an upper film and a lower film by the air gap AG1.

Next, as illustrated in FIGS. 10A and 10B, the buried insulation film 9 is etched using anisotropic etching such as RIE, so that a part of the sidewall of the floating gate electrode material 6′ is exposed in the state in which the air gap AG1 is closed by the buried insulation film 9.

Next, as illustrated in FIGS. 11A and 11D, an inter-electrode insulation film 7 is formed on the floating gate electrode material 6′ using a method such as CVD such that the sidewall of the floating gate electrode material 6′ is covered. Then, a control gate electrode material 8′ is formed on the inter-electrode insulation film 7 using a method such as CVD such that the sidewall of the inter-electrode insulation film 7 is covered. Since the air gap AG1 is closed by the buried insulation film 9, the air gap AG1 is not filled with the inter-electrode insulation film 7.

Then, a cap insulation film 12 and a hard mask M2 are sequentially formed on the control gate electrode material 8′ using a method such as CVD. In addition, as the cap insulation film 12 and the hard mask M2, for example, a silicon oxide film or a silicon nitride film may be used. Then, a resist pattern R3 with openings K3 is formed on the hard mask M2 using a photolithography technique.

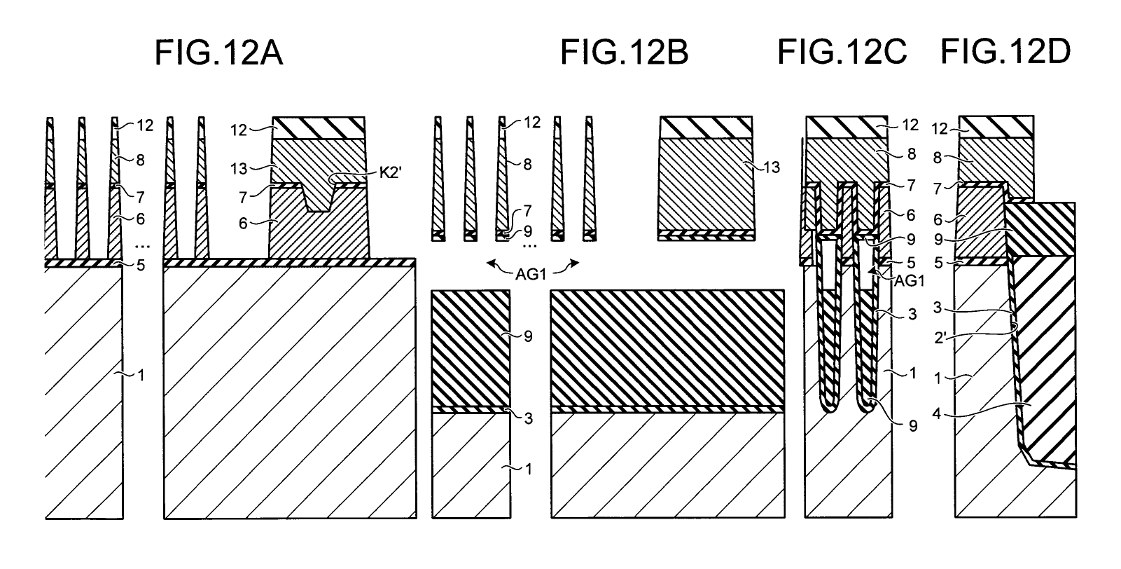

Next, as illustrated in FIGS. 12A and 12D, the hard mask M2 is patterned using the resist pattern R3 as a mask, and then the control gate electrode material 8′, the inter-electrode insulation film 7, and the floating gate electrode material 6′ are etched using the hard mask M2 as a mask, thereby forming a floating gate electrode 6 separated for each memory cell and forming control gate electrodes 8 and select gate electrodes 13, which are disposed on the floating gate electrodes 6 through the inter-electrode insulation film 7, in the word line direction DW. Here, an opening K2′ is formed in the inter-electrode insulation film 7 under the select gate electrode 13. The select gate electrode 13 is connected to the floating gate electrode 6 through the opening K2′

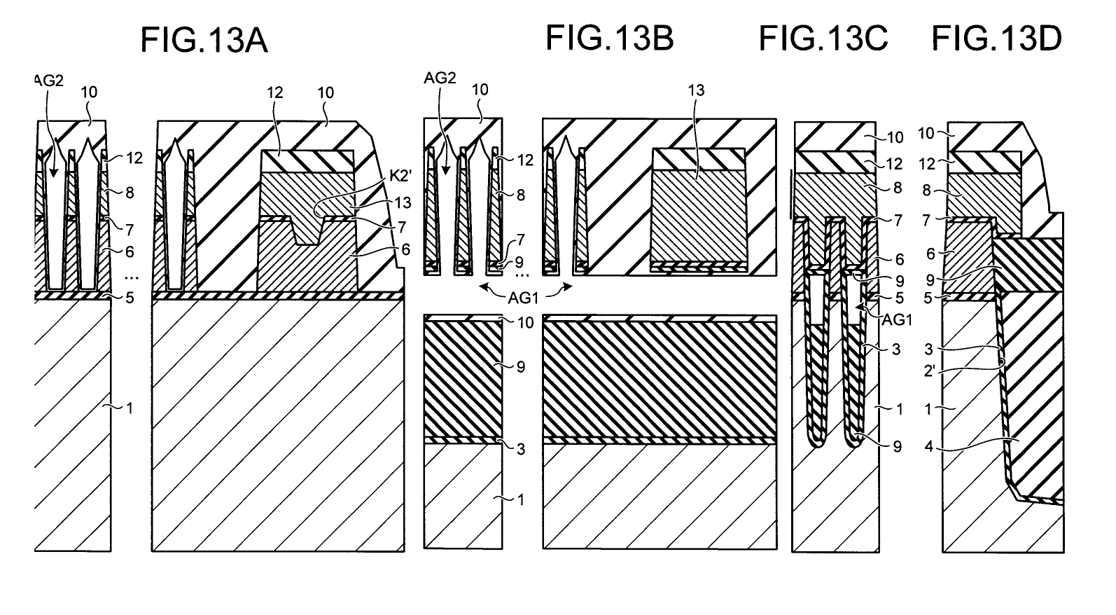

Next, as illustrated in FIGS. 13A and 13D, a cover insulation film 10 is formed on the cap insulation film 12 using a method such as plasma CVD such that the cover insulation film 10 extends between the control gate electrodes 8, and air gaps AG2 are formed between the floating gate electrodes 6 adjacent in the bit line direction DB. As the cover insulation film 10, for example, a CVD oxide film (a silicon oxide film) such as a plasma TEOS film or a plasma SiH₄ film may be used. When the cover insulation film 10 is formed on the cap insulation film 12, conditions having a poor coverage may be set in order to prevent the air gaps AG1 and AG2 from being buried by the cover insulation film 10.

Since the air gaps AG1 are formed based on the film formation conditions of the buried insulation film 9, it is not necessary to form the air gaps AG1 through the wet etching of the buried insulation film 9 after the inter-electrode insulation film 7 is formed. Consequently, even when the tunnel insulation film 5 and the inter-electrode insulation film 7 are made of the same material as the buried insulation film 9, it is possible to reduce parasitic capacitance between the floating gate electrodes 6 while preventing damage to the tunnel insulation film 5 and the inter-electrode insulation film 7.

Furthermore, the buried insulation film 4 is formed on the sidewall dielectric film 3 in the trench 2′, so that it is possible to prevent the sidewall dielectric film 3 in the trench 2′ from being etched when the sidewall dielectric film 3 in the trench 2 is etched, resulting in the sidewall dielectric film 3 in the trench 2′ being protected.

### Fourth Embodiment

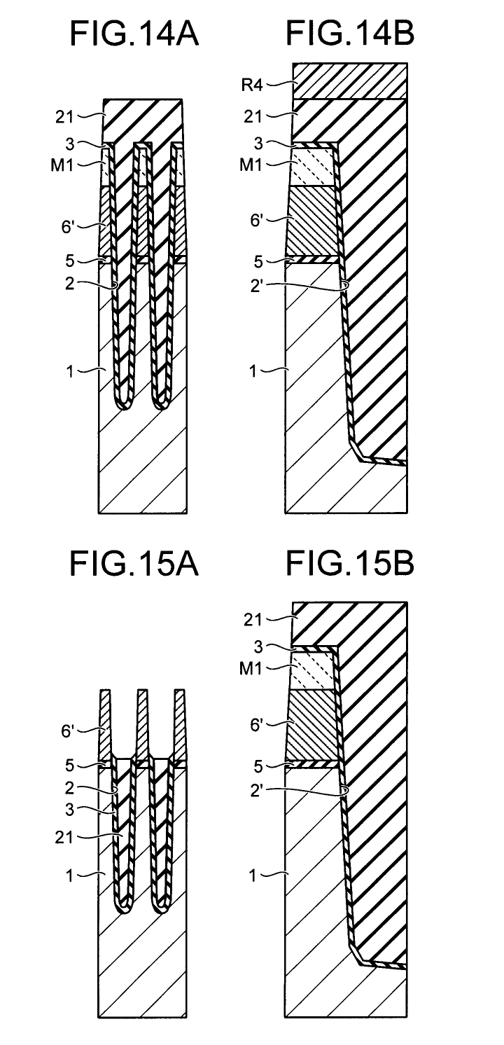

FIGS. 14A to 18A and FIGS. 14B to 18B are sectional views illustrating a method of manufacturing a non-volatile semiconductor memory device according to forth embodiment. In detail, FIGS. 14A, 15A, 16A, 17A and 18A are sectional views taken along line C-C of FIG. 2, and FIGS. 14B, 15B, 16B, 17B and 18B are sectional views taken along a peripheral circuit unit.

In FIGS. 14A and 14B, the trenches 2 and 2′ are formed in the semiconductor substrate 1 by performing the same processes as FIGS. 3 to 5. Next, a sidewall dielectric film 3 is formed on a hard mask M1 using a method such as CVD such that the sidewalls of the trenches 2 and 2′ are covered. Then, a buried sacrificial film 21 is formed on the sidewall dielectric film 3 using a method such as coating or CVD such that the entire trenches 2 and 2′ are buried. As the buried sacrificial film 21, for example, a carbon-based coating film, a carbon-based CVD film and the like may be used. Then, a resist pattern R4 covering a peripheral circuit unit is formed on the buried sacrificial film 21 using a lithography technique.

Next, as illustrated in FIGS. 15A and 15B, the sidewall dielectric film 3 is etched using anisotropic etching such as RIE while the buried sacrificial film 21 in the trench 2 is being made thin, and a part of the sidewall of the floating gate electrode material 6′ is exposed such that the upper end of the sidewall dielectric film 3 reaches the sidewall of the floating gate electrode material 6′. The sidewall dielectric film 3 may be provided at the upper end thereof with an inclined surface that reflects a raw material gas of a buried insulation film 9 when the buried insulation film 9 is buried in the trench 2′ by HDP-CVD.

At this time, the buried sacrificial film 21 is provided on the sidewall dielectric film 3, so that it is possible to use the buried sacrificial film 21 as an etching stopper when the sidewall dielectric film 3 is etched, which improves the controllability of the etching of the sidewall dielectric film 3 and protects the sidewall dielectric film 3 remaining in the trenches 2 and 2′.

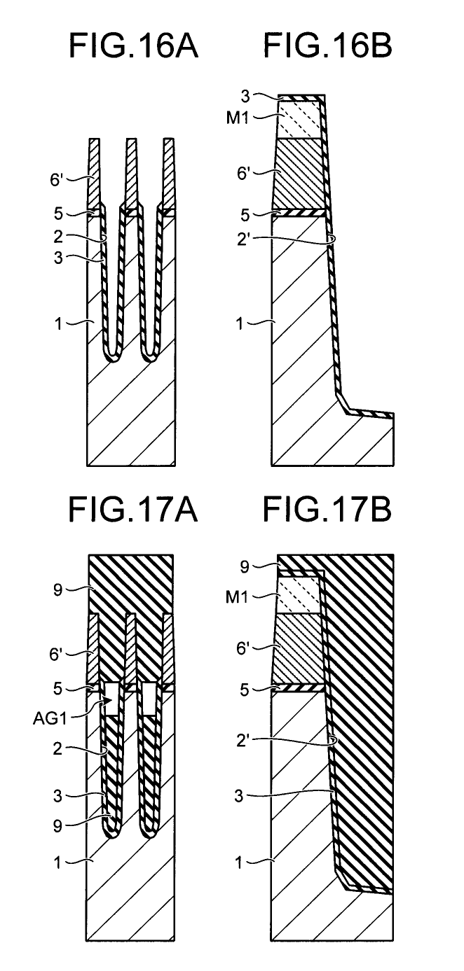

Next, as illustrated in FIGS. 16A and 16B, the buried sacrificial film 21 in the trenches 2 and 2′ is removed using a method such as ashing. A carbon-based material is used as the buried sacrificial film 21, so that it is possible to remove the buried sacrificial film 21 using an oxygen-based gas. Since it is not necessary to use a chlorine-based gas, it is possible to suppress damage to Si.

Next, as illustrated in FIGS. 17A and 17B, a buried insulation film 9 is formed on the floating gate electrode material 6′ using a method such as HDP-CVD in a way of filling the trenches 2 and 2′. According to the HDP-CVD, the raw material gas of the buried insulation film 9 is reflected by the inclined surface of the sidewall dielectric film 3, and is reabsorbed in the floating gate electrode material 6′ on the sidewall dielectric film 3 without being reabsorbed in the trench 2 with a narrow width. Therefore, an air gap AG1 is formed in the buried insulation film 9 in the vicinity of the upper end of the sidewall dielectric film 3, and the buried insulation film 9 is divided into an upper film and a lower film by the air gap AG1.

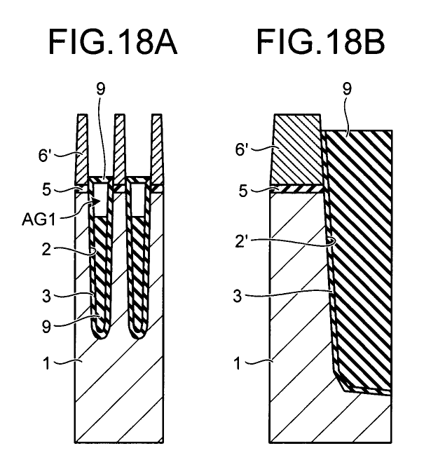

Next, as illustrated in FIGS. 18A and 18B, the buried insulation film 9 is etched using anisotropic etching such as RIE, so that a part of the sidewall of the floating gate electrode material 6′ is exposed in the state in which the air gap AG1 is closed by the buried insulation film 9. Then, the same processes as FIGS. 11 to 13 are performed, thereby forming the configuration of FIG. 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a plurality of memory cells provided on a semiconductor substrate and configured to include control gate electrodes that are provided on charge accumulation layers with an inter-electrode insulation film interposed the control gate electrodes and the charge accumulation layers;
a air gap provided to extend between the charge accumulation layers adjacent to each other in a word line direction; and
insulation film, each being disposed below the inter-electrode insulation film and divided into an upper part and a lower part by the air gap.

2. The non-volatile semiconductor memory device according to claim 1,
wherein the air gap exists at a position lower than a lower surface of the charge accumulation layer.

3. The non-volatile semiconductor memory device according to claim 1,
wherein the air gap is located in a trench that is provided in the semiconductor substrate to separate active areas of the memory cells from one another.

4. The non-volatile semiconductor memory device according to claim 1,
wherein the air gap is continuously formed in the trench and over adjacent memory cells.

5. The non-volatile semiconductor memory device according to claim 3,
wherein the lower part of the insulation film divided by the air gap is embedded in the trench.

6. The non-volatile semiconductor memory device according to claim 5, further comprising a sidewall dielectric film provided on a sidewall of the trench and provided with an upper end including an inclined surface.

7. The non-volatile semiconductor memory device according to claim 4, further comprising a select gate transistor which includes a select gate electrode and is connected to an active area of the memory cell,
wherein the air gap exists below the select gate electrode while extending along the trench.

8. The non-volatile semiconductor memory device according to claim 7,
wherein the air gap penetrates through a structure disposed below the select gate electrode and extends along the trench.

9. The non-volatile semiconductor memory device according to claim 1,
wherein the insulation film which is divided into the upper part and the lower part by the air gap is equal in a material and hence equal in film quality.

10. The non-volatile semiconductor memory device according to claim 1,
wherein the upper part of the insulation film resulting from the division by the air gap exists at a position lower than an upper surface of the charge accumulation layer.

11. The non-volatile semiconductor memory device according to claim 10,
wherein the air gap is formed such that the inter-electrode insulation film reaches a sidewall of the charge accumulation layer.

12. A non-volatile semiconductor memory device comprising:
a plurality of memory cells provided on a semiconductor substrate and configured to include control gate electrodes that are disposed on charge accumulation layers with an inter-electrode insulation film interposed between the control gate electrodes and the charge accumulation layers;
a first air gap provided between the charge accumulation layers adjacent to each other in a word line direction;
an insulation film disposed below the inter-electrode insulation film and divided into an upper part and a lower part by the first air gap; and
a second air gap provided between the charge accumulation layers adjacent each other in a bit line direction.

13. The non-volatile semiconductor memory device according to claim 12,
wherein the first air gap is located in a trench that is provided in the semiconductor substrate to separate active areas of the memory cells from one another.

14. The non-volatile semiconductor memory device according to claim 12,
wherein the first air gap is continuously formed in the trench and over the memory cells adjacent in the bit line direction.

15. The non-volatile semiconductor memory device according to claim 14,
wherein the second air gap is continuously formed over the memory cells adjacent in the word line direction, and the first air gap and the second air gap are connected to each other at an intersection of the first air gap and the second air gap.

16. The non-volatile semiconductor memory device according to claim 12,
wherein the lower part of the insulation film divided by the first air gap is embedded in the trench, and the upper part of the insulation film divided by the first air gap exists at a position lower than an upper surface of the charge accumulation layer.

17. The non-volatile semiconductor memory device according to claim 16,
wherein the first air gap is formed such that the inter-electrode insulation film reaches a sidewall of the charge accumulation layer.

18. A method of manufacturing a non-volatile semiconductor memory device, the method comprising:
forming a floating gate electrode material on a semiconductor substrate such that a tunnel insulation film is interposed between the floating gate electrode material and the semiconductor substrate;
forming a trench in the semiconductor substrate in a way of passing through the floating gate electrode material and the tunnel insulation film so as to extend in a bit line direction;
forming a sidewall dielectric film on a sidewall of the trench such that an upper end of the sidewall dielectric film reaches the floating gate electrode material;
forming an insulation film, which covers the floating gate electrode material and is buried in the trench while having an air gap therein, using a high density plasma chemical vapor deposition process;
making a sidewall of the floating gate electrode material to be exposed by allowing the insulation film to be thin such that the insulation film remains above the air gap;
forming an inter-electrode insulation film on the insulation film such that the floating gate electrode material is covered;
forming a control gate electrode material on the inter-electrode insulation film; and
patterning the control gate electrode material, the inter-electrode insulation film, and the floating gate electrode material, thereby forming floating gate electrodes separated from each other for each memory cell and forming control gate electrodes, which are disposed on the floating gate electrodes to extend in a word line direction.

19. The method according to claim 18,
wherein the forming of the sidewall dielectric film on the sidewall of the trench such that the upper end of the sidewall dielectric film reaches the floating gate electrode material includes:
allowing the sidewall dielectric film to be buried in the trench such that an air gap is formed in the trench; and
etching back the sidewall dielectric film such that the upper end of the sidewall dielectric film reaches the floating gate electrode material.

20. The method according to claim 18,
wherein the forming of the sidewall dielectric film on the sidewall of the trench such that the upper end of the sidewall dielectric film reaches the floating gate electrode material includes:
forming the sidewall dielectric film on the floating gate electrode material such that the sidewall of the trench is covered;
forming a sacrificial film on the sidewall dielectric film such that the trench is buried;
etching back the sacrificial film such that the upper end of the sacrificial film reaches the floating gate electrode material; and
etching back the sidewall dielectric film exposed from the sacrificial film.
